(19) United States
(12) Patent Application Publication
(10) Pub. No.: US 2003/0048114 A1
(43) Pub. Date: Mar. 13, 2003

(54) Output buffer of semiconductor device

(75) Inventors: Setsu Kondoh, Hyogo (JP); Motomu Ukita, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/136,391

(22) Filed: May 2, 2002

(30) Foreign Application Priority Data
Sep. 13, 2001 (JP) 2001-277471(P)

(51) Int. Cl. H03K 19/094

(52) U.S. Cl. 326/83

(57) ABSTRACT

An output buffer of a semiconductor memory device includes two N channel pull-down transistors both caused to become conductive in response to a falling edge of an internal data signal. One of the two N channel MOS transistors is caused to become nonconductive in the period starting from the time when the level of an external data signal falls beyond a reference potential to the time when the level of the external data signal reaches L level. Accordingly, noise generated on a line of the ground potential can be reduced without deterioration of the falling speed of the external data signal from H level to the reference potential.

### BACKGROUND OF THE INVENTION

1. Field of the Invention

The present invention relates to output buffers of semiconductor devices. In particular, the invention relates to an output buffer of a semiconductor device that outputs an external signal in response to an internal signal.

2. Description of the Background Art

An output buffer is conventionally provided in a semiconductor memory device such as a DRAM (dynamic random access memory) and SRAM (static random access memory) for outputting an external data signal in response to an internal data signal generated by internal circuitry.

FIG. 8 is a circuit diagram showing a structure of an output buffer 30 of a conventional semiconductor memory device. Referring to FIG. 8, output buffer 30 includes an inverter 31, a P channel MOS transistor 32 and an N channel MOS transistor 33. P channel MOS transistor 32 is connected between a line of power supply potential VCC and an output node N32 and N channel MOS transistor 33 is connected between output node N32 and a line of ground potential GND. Internal data signal DOI is supplied to respective gates of MOS transistors 32 and 33 via inverter 31. A signal appearing on output node N32 is external data signal DO.

When internal data signal DOI falls from a logical high level to a logical low level (hereinafter referred to H and L levels respectively), output signal ZDOI of inverter 31 rises from L level to H level to make P channel MOS transistor 32 nonconductive and N channel MOS transistor 33 conductive, so that external data signal DO falls from H level to L level.

When internal data signal DOI rises from L level to H level, output signal ZDOI of inverter 31 falls from H level to L level to make P channel MOS transistor 32 conductive and N channel MOS transistor 33 nonconductive, so that external data signal DO rises from L level to H level.

This output buffer 30, however, has a following problem. Each time the logic level of internal data signal DOI is inverted, current suddenly flows to increase the rate of change of current, dI/dt, which causes noise on a power supply line (particularly the line of ground potential GND) within a chip due to the self-inductance of the power supply line. As a result, malfunction of internal circuitry occurs. Although the noise level can be lowered by reducing the size of MOS transistors 32 and 33 to decrease current change rate dI/dt, the response speed of output buffer 30 would deteriorate.

FIG. 9 is a circuit block diagram showing a structure of an output buffer 35 of another conventional semiconductor memory device. Referring to FIG. 9, output buffer 35 includes an inverter 40, P channel MOS transistors 41 and 42, N channel MOS transistors 43 and 44, a delay circuit 45 and an NOR gate 46. Delay circuit 45 has a predetermined delay time T.

P channel MOS transistors 41 and 42 are connected in parallel between a line of power supply potential VCC and an output node N42. N channel MOS transistors 43 and 44 are connected in parallel between output node N42 and a line of ground potential GND. Internal data signal DOI is supplied to respective gates of MOS transistors 41 to 43 via inverter 40. Internal data signal DOI is also supplied to one input node of NOR gate 46 via delay circuit 45 and supplied directly to the other input node of NOR gate 46. Output signal φ46 of NOR gate 46 is supplied to the gate of N channel MOS transistor 44.

FIG. 10 is a timing chart illustrating an operation of output buffer 35 shown in FIG. 9. Referring to FIG. 10, internal data signal DOI has H level in the initial state. Accordingly, output signal ZDOI of inverter 40 and output signal φ46 of NOR gate 46 both have L level so that P channel MOS transistors 41 and 42 are conductive while N channel MOS transistors 43 and 44 are nonconductive and signal DO accordingly has H level.

At a certain time t0, internal data signal DOI is lowered from H level to L level and accordingly output signal ZDOI of inverter 44 is caused to rise from L level to H level. Then, P channel MOS transistors 41 and 42 are rendered nonconductive while N channel MOS transistor 43 is rendered conductive so that data signal DO has its level falling from H level to L level. At this time, although internal data signal DOI falls to L level, output signal DOI′ of delay circuit 45 remains at H level until delay time T3 of delay circuit 45 expires. Then, output signal φ46 of NOR gate 46 remains at L level and thus N channel MOS transistor 44 does not become conductive. Therefore, the level of data signal DO falls relatively gradually.

At time t1 when delay time T3 of delay circuit 45 starting from time t0 expires, output signal DOI′ of delay circuit 45 falls from H level to L level and signal φ46 rises from L level to H level so that N channel MOS transistor 44 becomes conductive. N channel MOS transistors 43 and 44 are thus conductive to cause the level of data signal DO to sharply decrease beyond reference potential VR to reach L level at time t2, reference potential VR being used for determining whether data signal DO has L level or H level.

This output buffer 35 causes, in response to a falling edge of internal data signal DOI (corresponding to time t0), one of two N channel pull-down MOS transistors 43 and 44, namely N channel MOS transistor 43 to be conductive. Output buffer 35 further causes the other N channel MOS transistor 44 to be conductive after a lapse of predetermined time T3 from time t0. In this way, the level of external data signal DO is lowered in two steps. Consequently, current change rate dI/dt decreases and thus noise generated on the line of ground potential GND can be reduced.

There is still a problem in such output buffer 35. Specifically, the period from t0 to t1 must be long enough to enhance the noise reduction effect and accordingly the response speed deteriorates.

### SUMMARY OF THE INVENTION

One object of the present invention is to provide an output buffer of a semiconductor device having a low noise and a high response speed.

An output buffer of a semiconductor device according to the present invention includes first and second transistors connected in parallel between an output node for outputting an external signal and a line of a first power supply potential and includes a first control circuit causing the first and second transistors to be conductive according to a change of an internal signal from a first logic level to a second logic level and causing the first transistor to be nonconductive before the output node has its potential changing to the first power supply potential. In this way, a greater current flows first between the output node and the line of the first power supply potential according to the change of the internal signal from the first logic level to the second logic level, and then a smaller current flows between the output node and the line of the first power supply potential. Noise generated on the line of the first power supply potential can thus be reduced without deterioration of the response speed.

Preferably, the first control circuit causes the first transistor to be nonconductive in a period from time when the potential of the output node changes beyond a reference potential to time when the potential reaches the first power supply potential, the reference potential being used for determining whether the external signal has the first logic level or the second logic level. It is then possible to prevent extension of the period from the time when the logic level of the internal signal changes to the time when the potential of the output node goes beyond the reference potential.

More preferably, the output buffer further includes third and fourth transistors connected in parallel between the output node and a line of a second power supply potential, and includes a second control circuit causing the third and fourth transistors to be conductive according to a change of the internal signal from the second logic level to the first logic level and causing the third transistor to be nonconductive before the output node has its potential changing to the second power supply potential. In this case, a greater current flows first between the output node and the line of the second power supply potential according to the change of the internal signal from the second logic level to the first logic level, and then a smaller current flows between the output node and the line of the second power supply potential. Noise generated on the line of the second power supply potential can thus be reduced without deterioration of the response speed.

Still more preferably, the second control circuit causes the third transistor to be nonconductive in a period from time when the potential of the output node changes beyond a reference potential to time when the potential reaches the second power supply potential, the reference potential being used for determining whether the external signal has the first logic level or the second logic level. It is thus possible to prevent extension of the period from the time when the logic level of the internal signal changes to the time when the potential of the output node goes beyond the reference potential.

Another output buffer of a semiconductor device according to the present invention includes first and second transistors connected in parallel between an output node for outputting an external signal and a line of a first power supply potential, and includes a first control circuit causing the first and second transistors to be conductive according to a change of the internal signal from a first logic level to a second logic level and causing the first transistor to be nonconductive after a lapse of a predetermined first time. In this way, a greater current flows first between the output node and the line of the first power supply potential according to the change of the internal signal from the first logic level to the second logic level, and then a smaller current flows between the output node and the line of the first power supply potential. Noise generated o n the line of the first power supply potential can thus be reduced without deterioration of the response speed.

Preferably, the output buffer further includes third and fourth transistors connected in parallel between the output node and a line of a second power supply potential, and includes a second control circuit causing the third and fourth transistors to be conductive according to a change of the internal signal from the second logic level to the first logic level and causing the third transistor to be nonconductive after a lapse of a predetermined second time. In this case, a greater current flows first between the output node and the line of the second power supply potential according to the change of the internal signal from the second logic level to the first logic level, and then a smaller current flows between the output node and the line of the second power supply potential. Noise generated on the line of the second power supply potential can thus be reduced without deterioration of the response speed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing an entire structure of a semiconductor memory device according to a first embodiment of the present invention.

FIG. 2 is a circuit block diagram showing a structure of an output buffer in FIG. 1.

FIG. 3 is a circuit block diagram showing a structure of a pulse generating circuit in FIG. 2.

FIG. 4 is a timing chart illustrating an operation of the output buffer shown in FIGS. 2 and 3.

FIG. 5 is a circuit block diagram showing a structure of an output buffer of a semiconductor memory device according to a second embodiment of the present invention.

FIG. 6 is a circuit block diagram showing a structure of a pulse generating circuit 21 in FIG. 5.

FIG. 7 is a timing chart illustrating an operation of the output buffer shown in FIGS. 5 and 6.

FIG. 8 is a circuit diagram showing a structure of an output buffer of a conventional semiconductor memory device.

FIG. 9 is a circuit block diagram showing a structure of an output buffer of another conventional semiconductor memory device.

FIG. 10 is a timing chart illustrating an operation of the output buffer shown in FIG. 9.

### DESCRIPTION OF THE PREFERRED EMBODIMENTS

First Embodiment

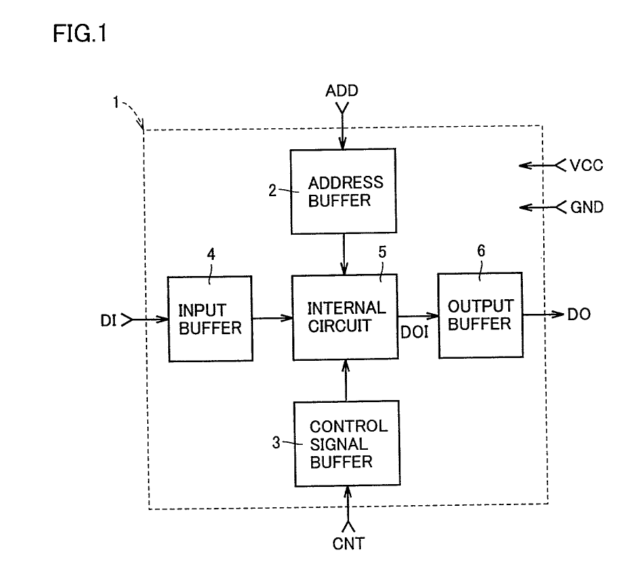

FIG. 1 is a block diagram showing a structure of a semiconductor memory device according to a first embodiment of the present invention. Referring to FIG. 1, the semiconductor memory device includes an address buffer 2, a control signal buffer 3, an input buffer 4, an internal circuit 5, and an output buffer 6. The semiconductor memory device is driven by externally applied power supply potential VCC and ground potential GND.

Address buffer 2 provides externally supplied address signal ADD to internal circuit 5. Control signal buffer 3 provides externally supplied control signal CNT to internal circuit 5. Input buffer 4 provides externally supplied write data signal DI to internal circuit 5.

Internal circuit 5 includes a plurality of memory cells arranged in rows and columns. A specific address signal ADD is allocated in advance to each memory cell. Internal circuit 5 is controlled by external control signal CNT to write, for a write operation, write data signal DI into a memory cell corresponding to external address signal ADD and read, for a read operation, data signal DOI in a memory cell corresponding to external address signal ADD to provide the read data to output buffer 6. Output buffer 6 outputs, in response to internal data signal DOI supplied from internal circuit 5, read data signal DO to any circuitry on the outside of the semiconductor memory device.

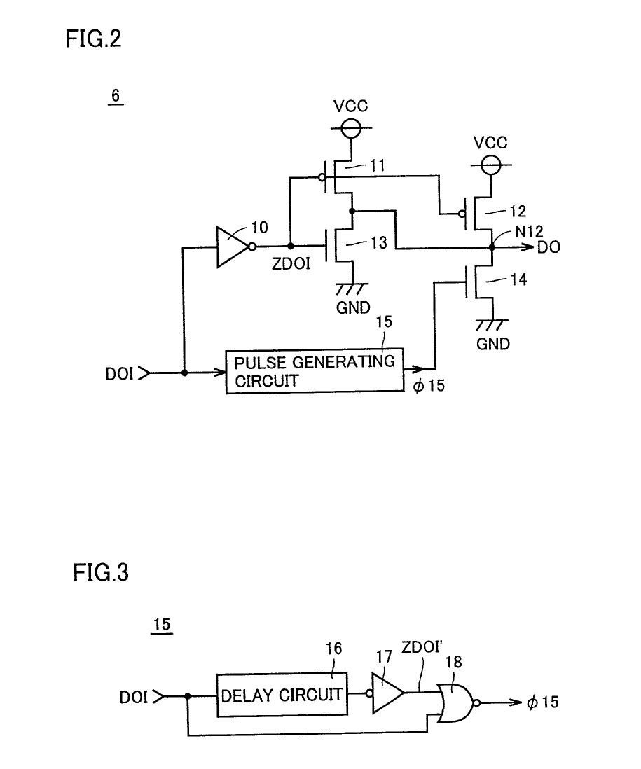

Referring to FIG. 2, output buffer 6 includes an inverter 10, P channel MOS transistors 11 and 12, N channel MOS transistors 13 and 14, and a pulse generating circuit 15. P channel MOS transistors 11 and 12 are connected in parallel between a line of power supply potential VCC and an output node N12. N channel MOS transistors 13 and 14 are connected in parallel between output node N12 and a line of ground potential GND. Internal data signal DOI generated by internal circuit 5 is input to respective gates of P channel MOS transistors 11 and 12 and N channel MOS transistor 13 via inverter 10 and also input to pulse generating circuit 15. In response to falling of internal data signal DOI from H level to L level, pulse generating circuit 15 causes signal φ15 to rise to H level like a pulse. Signal φ15 is input to the gate of N channel MOS transistor 14.

Pulse generating circuit 15 is described in more detail in conjunction with FIG. 3. Pulse generating circuit 15 includes a delay circuit 16, an inverter 17 and an NOR gate 18. Delay circuit 16 has a predetermined delay time T1. Internal data signal DOI is input to one input node of NOR gate 18 via delay circuit 16 and inverter 17 and also input directly to the other input node of NOR gate 18. An output signal of NOR gate 18 is output signal φ15 of pulse generating circuit 15.

When internal data signal DOI has H level, output signal ZDOI′ of inverter 17 has L level and output signal φ15 of NOR gate 18 has L level. When internal data signal DOI falls from H level to L level, signal ZDOI′ remains at L level until delay time T1 of delay circuit 16 expires. When delay time T1 has passed, signal ZDOI′ rises from L level to H level. Then, in response to the falling edge of internal data signal DOI, signal φ15 is caused to rise to H level like a pulse for predetermined time T1 only.

When internal data signal DOI has L level, output signal ZDOI′ of inverter 17 has H level and output signal φ15 of NOR gate 18 has L level. When internal data signal DOI rises from L level to H level, signal ZDOI′ stays at H level until delay time T1 of delay circuit 16 expires. After a lapse of delay time T1, signal ZDOI′ falls from H level to L level. Then, signal φ15 remains at L level.

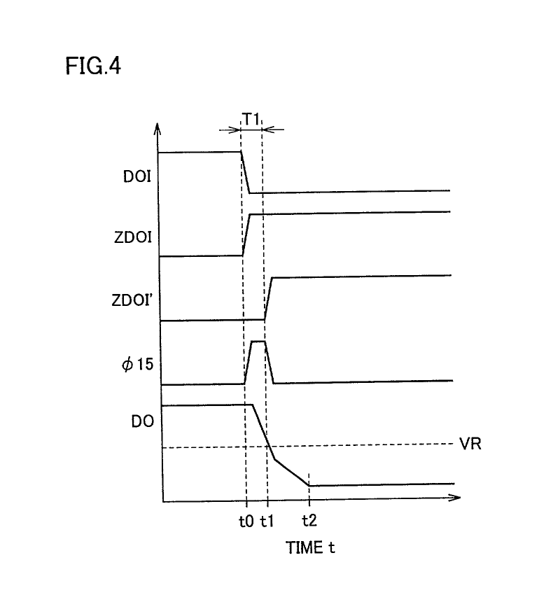

FIG. 4 is a timing chart illustrating an operation of output buffer 6 shown in FIGS. 2 and 3. Referring to FIG. 4, in the initial state, internal data signal DOI is set at H level. Accordingly, output signal ZDOI of inverter 10 has L level so that P channel MOS transistors 11 and 12 are conductive and N channel MOS transistor 13 is nonconductive and data signal DO has H level. At this time, output signal φ15 of pulse generating circuit 15 has L level so that N channel MOS transistor 14 is nonconductive.

At a certain time t0, internal data signal DOI is caused to fall from H level to L level. Accordingly, output signal ZDOI of inverter 10 rises from L level to H level, P channel MOS transistors 11 and 12 become nonconductive and N channel MOS transistor 13 becomes conductive. Moreover, output signal ZDOI′ of inverter 17 and internal data signal DOI both have L level, signal φ15 rises to H level, and then N channel MOS transistor 14 becomes conductive. As P channel MOS transistors 11 and 12 are nonconductive while N channel MOS transistors 13 and 14 are conductive, data signal DO has its level sharply falls from H level toward L level.

Then, at time t1 when delay time T1 of delay circuit 16 starting from time to expires, output signal ZDOI′ of inverter 17 is caused to rise from L level to H level and accordingly signal φ15 falls to L level so that N channel MOS transistor 14 becomes nonconductive. Delay time T1 of delay circuit 16 is defined to allow N channel MOS transistor 14 to become nonconductive when the level of data signal DO falls below reference potential VR. Here, reference potential VR refers to the potential used for determining whether data signal DO has L level or H level. When N channel MOS transistor 14 becomes nonconductive, the current flowing from output node N12 into the line of ground potential GND becomes smaller and thus the level of data signal DO falls relatively gradually to reach L level (time t2). At this time, the decreased current from output node N12 to the line of ground potential GND results in decrease of current change rate dI/dt. Therefore, noise generated on the line of ground potential GND can be reduced.

When internal data signal DOI is caused to rise from L level to H level, output signal ZDOI of inverter 10 falls from H level to L level so that P channel MOS transistors 11 and 12 become conductive while N channel MOS transistor 13 becomes nonconductive. Since output signal ZDOI′ of inverter 17 is already at H level, output signal φ15 of pulse generating circuit 15 stays at L level and thus N channel MOS transistor 14 remains in the nonconductive state. As P channel MOS transistors 11 and 12 are thus conductive while N channel MOS transistors 13 and 14 are nonconductive, the level of data signal DO abruptly rises from L level to H level.

According to the first embodiment, in response to a falling edge of internal data signal DOI, two N channel pull-down transistors 13 and 14 are both rendered conductive. Then, one of the two N channel MOS transistors 13 and 14, namely N channel MOS transistor 14, is rendered nonconductive in the period from the time when the level of external data signal DO falls beyond reference potential VR to the time when the level of external data signal DO reaches L level. In this way, the noise generated on the line of ground potential GND can be reduced without deterioration of the falling speed of external data signal DO from H level to reference potential VR.

Second Embodiment

FIG. 5 is a circuit block diagram showing a structure of an output buffer 20 of a semiconductor memory device according to a second embodiment of the present invention. Referring to FIG. 5, output buffer 20 in FIG. 5 differs from output buffer 6 in FIG. 2 in that the former output buffer additionally includes a pulse generating circuit 21. Pulse generating circuit 21 causes, in response to rise of output signal ZDOI of an inverter 10 from L level to H level, signal φ21 to fall to L level like a pulse. Signal φ21 is supplied to the gate of a P channel MOS transistor 12.

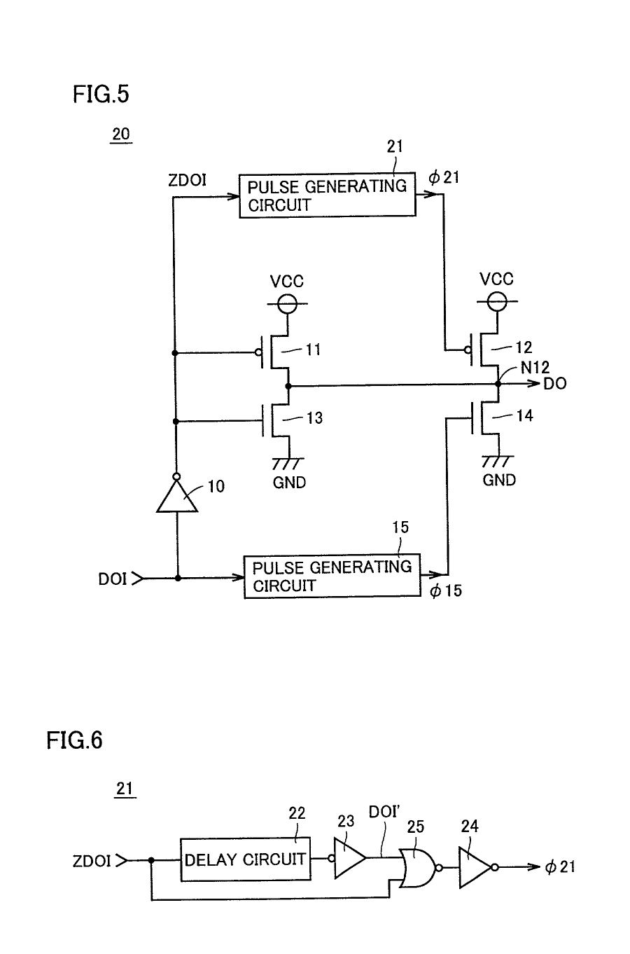

More specifically, as shown in FIG. 6, pulse generating circuit 21 includes a delay circuit 22, inverters 23 and 24 and an NOR gate 25. Delay circuit 22 has a predetermined delay time T2. Output signal ZDOI of inverter 10 is supplied to one input node of NOR gate 25 via delay circuit 22 and inverter 23 and also supplied to the other input node of NOR gate 25. An output signal of NOR gate 25 is inverted by inverter 24 and the inverted signal is supplied as output signal φ21 from pulse generating circuit 21.

When output signal ZDOI of inverter 10 has H level (internal data signal DOI has L level), output signal DOI′ of inverter 23 has L level and output signal φ21 of inverter 24 has H level. When signal ZDOI is caused to fall from H level to L level, signal DOI′ remains at L level until delay time T2 of delay circuit 22 expires. After a lapse of delay time T2, signal DOI′ rises from L level to H level. Accordingly, in response to the falling edge of signal ZDOI (rising edge of internal data signal DOI), signal φ21 is caused to fall to L level to stay there for predetermined time T2 only like a pulse.

When output signal ZDOI of inverter 10 has L level (internal data signal DOI has H level), output signal DOI′ of inverter 23 has H level and output signal φ21 of inverter 24 has H level. When signal ZDOI is caused to rise from L level to H level, signal DOI′ stays at H level until delay time T2 of delay circuit 22 expires and then falls from H level to L level after a lapse of delay time T2. Then, signal φ21 remains at H level.

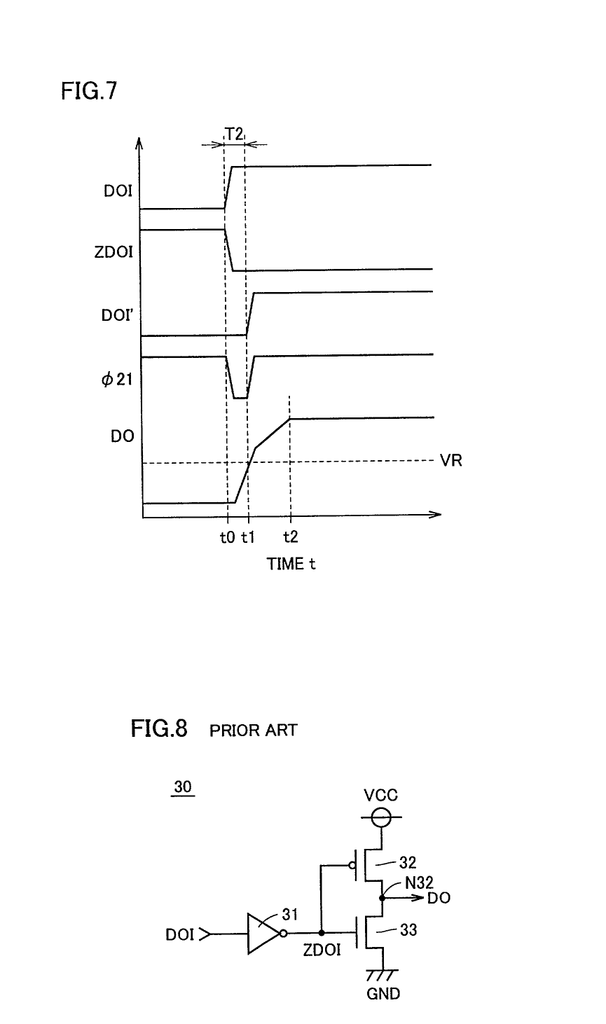

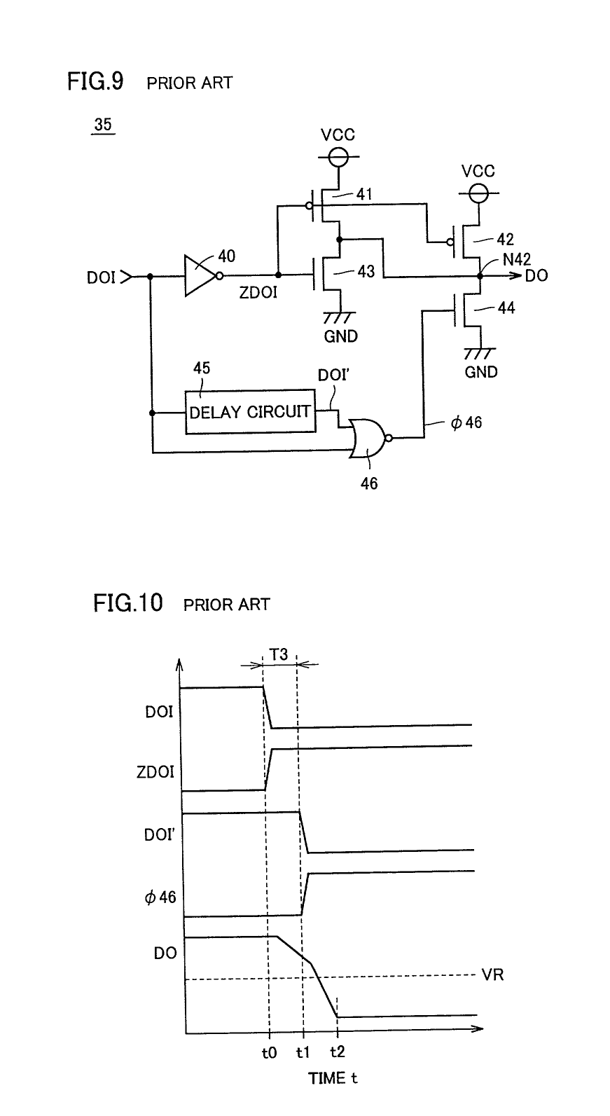

FIG. 7 is a timing chart illustrating an operation of output buffer 20 shown in FIGS. 5 and 6. Referring to FIG. 7, in the initial state, internal data signal DOI is set at L level. Accordingly, output signal ZDOI of inverter 10 has H level, P channel MOS transistor 11 is nonconductive, N channel MOS transistor 13 is conductive, and thus data signal DO has L level. At this time, output signals φ21 and φ15 of respective pulse generating circuits 21 and 15 have H and L levels respectively so that P channel MOS transistor 12 and N channel MOS transistor 14 are both nonconductive.

At a certain time t0, internal data signal DOI is caused to rise from L level to H level. Then, output signal ZDOI of inverter 10 falls from H level to L level, P channel MOS transistor 11 becomes conductive and N channel MOS transistor 13 becomes nonconductive. Further, respective output signals ZDOI and DOI′ of inverters 10 and 23 are both at L level, signal φ21 falls to L level, and P channel MOS transistor 12 becomes conductive. As output signal ZDOI′ of inverter 17 shown in FIG. 3 is already at H level, output signal φ15 of pulse generating circuit 15 stays at L level and N channel MOS transistor 14 remains in the nonconductive state. Accordingly, P channel MOS transistors 11 and 12 are conductive while N channel MOS transistors 13 and 14 are nonconductive to cause the level of data signal DO to rise abruptly from L level toward H level.

Then, at time t1 when delay time T2 of delay circuit 22 starting from time t0 expires, output signal DOI′ of inverter 23 is caused to rise from L level to H level. Accordingly, signal φ21 rises to H level and P channel MOS transistor 12 becomes nonconductive. Delay time T2 of delay circuit 22 is defined to allow P channel MOS transistor 12 to become nonconductive when the level of data signal DO becomes higher than reference potential VR. When P channel MOS transistor 12 becomes nonconductive, the current flowing from the line of power supply potential VCC into output node N12 decreases and the level of data signal DO rises relatively gradually to reach H level (time t2). At this time, because of the reduced current flowing from the line of power supply potential VCC into output node N12, current change rate dI/dt decreases. Consequently, noise generated on the line of power supply potential VCC can be decreased.

When internal data signal DOI falls from H level to L level, output signal ZDOI of inverter 10 rises from L level to H level. On the other hand, output signal DOI′ of inverter 23 is already at H level. Therefore, signal φ21 remains at H level and P channel MOS transistor 12 stays in the nonconductive state. In this case, output buffer 20 operates in the same manner as that of output buffer 6 as shown in FIG. 4.

According to the second embodiment, two P channel pull-up transistors 11 and 12 are rendered conductive in response to a rising edge of internal data signal DOI. One of the two P channel MOS transistors 11 and 12, namely P channel MOS transistor 12, is rendered nonconductive in the period from the time when the level of external data signal DO exceeds reference potential VR to the time when external data signal DO reaches H level. In this way, the second embodiment provides the same effect as that of the first embodiment and further provides the advantage that the noise generated on the line of power supply potential VCC can be reduced without deterioration of the rising speed of external data signal DO from L level to reference potential VR.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An output buffer of a semiconductor device outputting an external signal in response to an internal signal, comprising:
first and second transistors connected in parallel between an output node for outputting said external signal and a line of a first power supply potential; and
a first control circuit causing said first and second transistors to be conductive according to a change of said internal signal from a first logic level to a second logic level and causing said first transistor to be nonconductive before said output node has its potential changing to said first power supply potential.

2. The output buffer of a semiconductor device according to claim 1, wherein
said first control circuit causes said first transistor to be nonconductive in a period from time when the potential of said output node changes beyond a reference potential to time when the potential reaches said first power supply potential, said reference potential being used for determining whether said external signal has the first logic level or the second logic level.

3. The output buffer of a semiconductor device according to claim 1, further comprising:
third and fourth transistors connected in parallel between said output node and a line of a second power supply potential; and
a second control circuit causing said third and fourth transistors to be conductive according to a change of said internal signal from the second logic level to the first logic level and causing said third transistor to be nonconductive before said output node has its potential changing to said second power supply potential.

4. The output buffer of a semiconductor device according to claim 3, wherein
said second control circuit causes said third transistor to be nonconductive in a period from time when the potential of said output node changes beyond a reference potential to time when the potential reaches said second power supply potential, said reference potential being used for determining whether said external signal has the first logic level or the second logic level.

5. An output buffer of a semiconductor device outputting an external signal in response to an internal signal, comprising:
first and second transistors connected in parallel between an output node for outputting said external signal and a line of a first power supply potential; and
a first control circuit causing said first and second transistors to be conductive according to a change of said internal signal from a first logic level to a second logic level and causing said first transistor to be nonconductive after a lapse of a predetermined first time.

6. The output buffer of a semiconductor device according to claim 5, further comprising:
third and fourth transistors connected in parallel between said output node and a line of a second power supply potential; and
a second control circuit causing said third and fourth transistors to be conductive according to a change of said internal signal from the second logic level to the first logic level and causing said third transistor to be nonconductive after a lapse of a predetermined second time.
